(19) United States
(12) Patent Application Publication
(10) Pub. No.: US 2003/0141946 A1
(43) Pub. Date: Jul. 31, 2003

(54) Film bulk acoustic resonator (FBAR) and the method of making the same

(76) Inventors: Richard C. Ruby, Menlo Park, CA (US); Teresa Volcjak, San Jose, CA (US); Urupattur C. Sridharan, San Jose, CA (US); Kuhn Seo, Union City, CA (US); Allen Chien, San Ramon, CA (US); Alexia P. Kekoa, Fremont, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/062,899

(22) Filed: Jan. 31, 2002

(51) Int. Cl. H03H 9/00

(52) U.S. Cl. 333/187

(57) ABSTRACT

An apparatus having a thin film bulk acoustic resonator (FBAR) with positively sloped bottom electrode and a method of making the same is disclosed. The resonator has a bottom electrode, a top electrode, and core material. The bottom electrode includes a positively sloped edge. To make the apparatus including the resonator, first, a bottom electrode layer is deposited. Then, the bottom electrode layer is dry etched to fabricate a bottom electrode having a positively sloped edge. Next, a core layer is fabricated above the bottom electrode. Finally, a top electrode is fabricated over the core layer.

### BACKGROUND

The present invention relates to acoustic resonators, and more particularly, to resonators that may be used as filters for electronic circuits.

The need to reduce the cost and size of electronic equipment has led to a continuing need for ever-smaller filter elements. Consumer electronics such as cellular telephones and miniature radios place severe limitations on both the size and cost of the components contained therein. Many such devices utilize filters that are tuned to precise frequencies. Hence, there has been a continuing effort to provide inexpensive, compact filter units.

One class of filters that has the potential for meeting these needs is constructed using thin film bulk acoustic resonators (FBAR's). These devices use bulk longitudinal acoustic waves in thin film piezoelectric (PZ) material. In one simple configuration, a layer of PZ material is sandwiched between two metal electrodes. The sandwich structure is preferably suspended in air by a support structure. When electric field is applied between the metal electrodes, the PZ material converts some of the electrical energy into mechanical energy in the form of mechanical waves. The mechanical waves propagate in the same direction as the electric field and reflect on the electrode/air interface. At a resonant frequency, the device acts as an electronic resonator.

Fabrication of such thin film resonators poses several challenges. Ideally, the thin film PZ material should be a continuous fully dense film; however, underlying features introduce inconsistent growth rate of nuclei causing voids and discontinuities in the PZ film deposition. Accordingly, there remains a need for improved fabricating techniques for alleviating such problems.

### SUMMARY

The need is met by the present invention. According to a first aspect of the present invention, an apparatus includes a resonator with a bottom electrode, a top electrode, and core material, the bottom electrode including a positively sloped edge. The positively sloped edge reduces voids and discontinuities in the PZ material fabricated above the bottom electrode.

According to another aspect of the present invention, a method for fabricating a resonator is disclosed. First, a bottom electrode layer is deposited. Then, the bottom electrode layer is dry etched to fabricate a bottom electrode having a positively sloped edge. Next, a core layer is fabricated above the bottom electrode. Finally, a top electrode is fabricated over the core layer.

Other aspects and advantages of the present invention will become apparent from the following detailed description, taken in combination with the accompanying drawings, illustrating by way of example the principles of the invention.

### BRIEF DESCRIPTION OF THE DRAWINGS

FIG. 1A is a simplified cross sectional side view of an apparatus including resonators;

FIG. 1B is a more detailed view of a portion of the apparatus of FIG. 1A;

FIGS. 2A, 2B, and 2C illustrate various stages of fabrication of the apparatus of FIG. 1A;

FIG. 2D illustrates a portion of an apparatus fabricated in accordance with an embodiment of the present invention; and

FIG. 3 is a simplified cross sectional side view of an apparatus in accordance with another embodiment of the present invention.

### DETAILED DESCRIPTION

As shown in the drawings for purposes of illustration, the present invention is embodied in apparatus and techniques for fabricating resonators while minimizing discontinuities of the core PZ material.

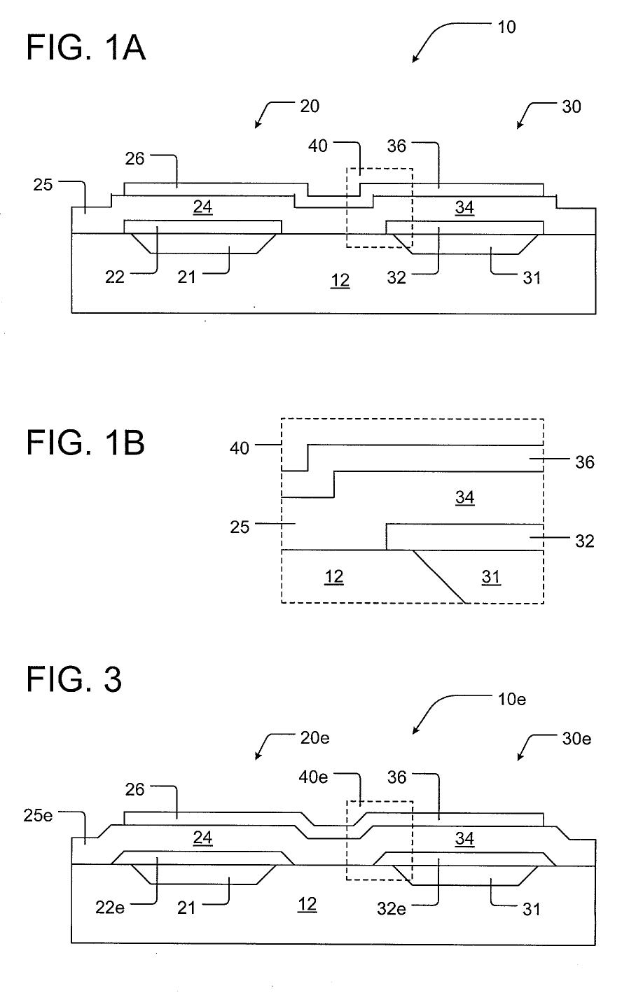

FIG. 1 is a simplified cross sectional side view of an apparatus 10 including a first resonator 20 and a second resonator 30. In the present example used to illustrate the present invention, the resonators 20 and 30 are thin film bulk acoustic resonators (FBAR's). As illustrated, multiple FBAR's are often fabricated on a single substrate for implementation of electronic signal filters. Here, the FBAR's 20 and 30 are fabricated on a substrate 12, a silicon substrate. The first resonator 20 includes a first bottom electrode 22, a first top electrode 26, and a core piezoelectric (PZ) material 24 sandwiched between the bottom and the top electrodes 22 and 26.

A second section 34 of the same PZ layer 25 is fabricated between a second bottom electrode 32 and a second top electrode 36. As illustrated in FIG. 1A, the top electrodes 26 and 36 may be connected. Further, the top electrodes 26 and 36, the bottom electrodes 22 and 32, or both may be connected to other circuits. For clarity, these connections are not illustrated in the figures.

The resonators 20 and 30 are acoustic resonators utilizing mechanical waves. For this reason, each of the illustrated resonators 20 and 30 is fabricated above a cavity 21 and 31, respectively. For example, U.S. Pat. No. 6,060,818 issued to Ruby et al. on May 9, 2000 illustrates this method and includes other details that may be applicable here with the present invention. FIG. 1B is a more detailed view of a portion 40 of the apparatus 10 of FIG. 1A.

In this document, designators “first” and “second” are used to conveniently distinguish between different occurrences of similar devices or parts of devices.

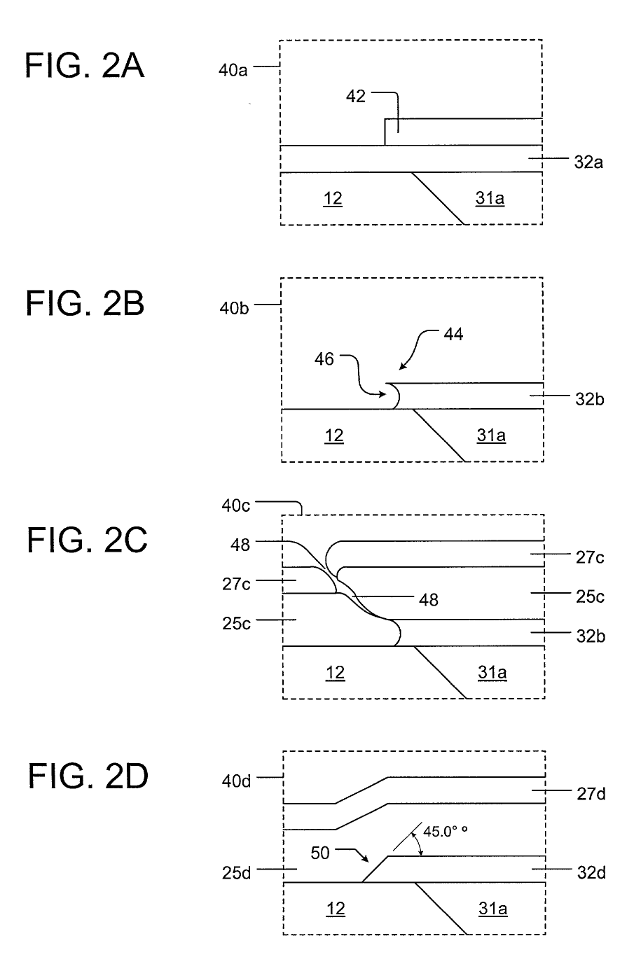

FIGS. 2A, 2B, and 2C illustrate various stages of fabrication of the apparatus 10 of FIG. 1A using more detailed views. FIG. 2A illustrates a portion 40a of an apparatus at an early stage of fabrication. The portion 40a of FIG. 2A may represent the portion 40 of FIG. 1B during an early stage of fabrication process. Alternatively, the portion 40a may represent a portion 40e of FIG. 3 during an early stage of fabrication process. FIG. 3 is discussed in more detail herein below. For convenience, parts of the portion 40a that are similar to corresponding parts in the portion 40 of FIG. 1B or portion 40e of FIG. 3 are assigned the same reference numerals, analogous but unfinished parts are assigned the same numeral accompanied by letter “a”, and different parts are assigned different reference numerals.

The apparatus 10 of FIG. 1A is fabricated on a substrate 12 by first etching a cavity 31 which is then filled by a sacrificial material such as glass 31a. Next, a bottom electrode layer 32a is deposited over the substrate 12 including over the sacrificial material 31a. Then, a mask 42 such as photoresist is placed over a portion of the bottom electrode layer 32a to protect the portion from etching.

Portion 40b of FIG. 2B represents the portion 40a of FIG. 2A following a wet etch operation to define the bottom electrode and subsequent removal of the mask 42 of FIG. 2A. For convenience, parts of the portion 40b that are similar to corresponding parts in the portion 40a of FIG. 2A are assigned the same reference numerals, analogous but unfinished parts are assigned the same numeral accompanied by letter “b”, and different parts are assigned different reference numerals. The wet etch operation creates an under-etch leaving the resulting bottom electrode 32b with an edge having a relatively sharp corner 44 and a concave edge 46. Problems posed by such edge are illustrated using FIG. 2C.

Portion 40c of FIG. 2C illustrates the portion 40b of FIG. 2B with additional layers (a PZ layer 25c and a top electrode layer 27c) fabricated over the bottom electrode 32b of FIG. 2B. For convenience, parts of the portion 40c that are similar to corresponding parts in the portion 40b of FIG. 2B are assigned the same reference numerals, analogous but unfinished parts are assigned the same numeral accompanied by letter “c”, and different parts are assigned different reference numerals. As illustrated, the PZ layer 25c and the top electrode layer 27c are prone to forming discontinuities or voids 48 resulting from the retrograde profile of a sharp corner and a concave edge shadowing during the PZ film deposition. The dielectric breakdown strength of the thin film is weakened by such discontinuities, lowering the power handling capability and the electrostatic discharge (ESD) tolerance of the device and other undesirable side effects.

This problem is overcome by dry etching to define the bottom electrode layer 32a of FIG. 2A. Result of dry etching the bottom electrode layer 32a of FIG. 2A is illustrated in FIG. 2D. Portion 40d of FIG. 2D illustrates the portion 40a of FIG. 2A following a dry etch operation and removal of the mask 42 of FIG. 2A and fabrication of a PZ layer 25d and a top electrode layer 27d over the resulting bottom electrode 32d. For convenience, parts of the portion 40d that are similar to corresponding parts in the portion 40a of FIG. 2A are assigned the same reference numerals, analogous but unfinished parts are assigned the same numeral accompanied by letter “d”, and different parts are assigned different reference numerals.

The dry etch operation creates a positively sloped edge generally pointed to by reference number 50. The positively sloped edge 50 allows for uniform deposition of the subsequent layers such as the PZ layer 25d and the top electrode layer 27d free of voiding and discontinuities.

FIG. 3 is a simplified cross sectional side view of an apparatus 10e in accordance with one embodiment of the present invention. For convenience, parts of the apparatus 10e that are similar to corresponding parts in the apparatus 10 of FIG. 1A are assigned the same reference numerals, analogous but unfinished parts are assigned the same numeral accompanied by letter “e”, and different parts are assigned different reference numerals. The apparatus 10e includes a first resonator 20e and a second resonator 30e, each having a bottom electrode with positively sloped edges.

Size of the first and the second resonators 20e and 30e depends upon the desired resonant frequency. For example, for a resonator having a resonant frequency of 1,900 MHz, dimensions of each of the resonators 20e and 30e may be about 150 by 200 microns covering approximately 30,000 square microns. At that frequency and size, top and bottom electrodes 26, 36, 22e, 32e may be in the range of about 1,500 to 6,000 Angstroms thick, and the core PZ layer 25e may be in the range of about 5,000 to 21,000 Angstroms (2.1 microns) thick. In one embodiment, the electrodes 26, 36, 22e, 32e include Molybdenum and the core PZ layer 25e includes Aluminum Nitride (AlN). The bottom electrodes and the top electrodes are generally made from conductive metals, and in particular, Molybdenum, Tungsten, and Aluminum are commonly used.

Referring again to FIG. 2D, to obtain the positively sloped edge 50, the apparatus is dry etched using conventional, known techniques. Dry etching the bottom electrode layer 32a causes photoresist 42 to gradually recede as the bottom electrode layer 32a is etched providing a gradually sloped edge. The slope may be nominally 45 degrees; however, the angle may be within a wide range such as 5 to 60 degrees and still produce desirable characteristics.

In one embodiment, for the dry etching process, oxygen (O₂), Sulfur hexafluoride (SF₆), and Helium (He) were used in 2 sccm (standard cubit centimeters per minute), 50 sccm, and 20 sccm quantities, respectively at a temperature within a range of 15 and 20 degrees, Celsius for 5-30 minutes.

From the foregoing, it will be appreciated that the present invention is novel and offers advantages over the current art. Although a specific embodiment of the invention is described and illustrated above, the invention is not to be limited to the specific forms or arrangements of parts so described and illustrated. For example, differing configurations, sizes, or materials may be used to practice the present invention. The invention is limited by the claims that follow.

What is claimed is:

1. An apparatus comprising a resonator including a bottom electrode, a top electrode and core material, the bottom electrode having a positively sloped edge.

2. The apparatus recited in claim 1 wherein the slope is at an angle ranging between 5 degrees and 60 degrees.

3. The apparatus recited in claim 1 wherein the resonator is a film bulk acoustic resonator (FBAR).

4. The apparatus recited in claim 1 wherein the bottom electrode comprises conductive metal.

5. The apparatus recited in claim 4 wherein the conductive metal is an element selected from a group consisting of Molybdenum, Tungsten, and Aluminum.

6. The apparatus recited in claim 1 wherein the bottom electrode comprises Molybdenum.

7. The apparatus recited in claim 1 wherein core material comprises piezoelectric (PZ) material.

8. The apparatus recited in claim 7 wherein PZ material comprises Aluminum Nitride (AlN).

9. The apparatus recited in claim 1 wherein the first bottom electrode comprises Molybdenum.

10. The apparatus recited in claim 1 further comprising another resonator including a bottom electrode having a positively sloped edge.

11. The apparatus recited in claim 1 wherein the resonator is fabricated on a substrate having a cavity under the resonator.

12. A method for fabricating a resonator, the method comprising:
depositing a bottom electrode layer;
dry etching the bottom electrode layer to fabricate a bottom electrode having a positively sloped edge;
fabricating a core layer above the bottom electrode; and
fabricating a top electrode above the core layer.

13. The method recited in claim 12 wherein the slope is at an angle ranging between 5 degrees and 60 degrees.

14. The method recited in claim 12 wherein the resonator is a film bulk acoustic resonator (FBAR).

15. The apparatus recited in claim 12 wherein the bottom electrode comprises conductive metal.

16. The apparatus recited in claim 15 wherein the conductive metal is an element selected from a group consisting of Molybdenum, Tungsten, and Aluminum.

17. The method recited in claim 12 wherein the bottom electrode comprises Molybdenum.

18. The method recited in claim 12 wherein core material comprises piezoelectric (PZ) material.

19. The method recited in claim 18 wherein PZ material comprises Aluminum Nitride (AlN).

20. The method recited in claim 19 wherein the first bottom electrode comprises Molybdenum.

21. The method recited in claim 12 further comprising another resonator including a bottom electrode having a positively sloped edge.

22. The apparatus recited in claim 12 wherein the resonator is fabricated on a substrate having a cavity under the resonator.
